(19) United States
(12) Patent Application Publication
(10) Pub. No.: US 2011/0056531 A1
(43) Pub. Date: Mar. 10, 2011

(54) METHOD FOR ENHANCING THE PERFORMANCE OF THERMOELECTRIC MATERIALS BY IRRADIATION-PROCESSING

(75) Inventors: Gregory P. Meisner, Ann Arbor, MI (US); Carlton D. Fuerst, Royal Oak, MI (US); Jihui Yang, Lakeshore (CA)

(73) Assignee: GM GLOBAL TECHNOLOGY OPERATIONS, INC., Detroit, MI (US)

(21) Appl. No.: 12/555,226

(22) Filed: Sep. 8, 2009

(51) Int. Cl. H01L 35/34

(52) U.S. Cl. 136/201

(57) ABSTRACT

One embodiment includes a method for enhancing thermoelectric properties in a thermoelectric material including irradiation processing.

### TECHNICAL FIELD

The field to which the disclosure relates generally includes thermoelectric material processing and, in particular, to the enhancement of thermoelectric materials by irradiation processing.

### BACKGROUND

Neutron and ion irradiation of materials causes defects that can affect material properties.

### SUMMARY OF EXEMPLARY EMBODIMENTS OF THE INVENTION

A method for enhancing thermoelectric properties in a thermoelectric material may be based on creating a large density of phonon-scattering sites by incorporating nanometer size internal defects in the thermoelectric material by irradiating the material by neutrons or other neutral or charged particles, or electromagnetic radiation (gamma or x-rays).

Other exemplary embodiments of the invention will become apparent from the detailed description provided hereinafter. It should be understood that the detailed description and specific examples, while disclosing exemplary embodiments of the invention, are intended for purposes of illustration only and are not intended to limit the scope of the invention.

### BRIEF DESCRIPTION OF THE DRAWINGS

Exemplary embodiments of the invention will become more fully understood from the detailed description and the accompanying drawings, wherein:

FIG. 1 is a schematic drawing of a process for irradiating a thermoelectric material to induce nano-scale defects and additional grain boundaries in accordance with an exemplary embodiment.

### DETAILED DESCRIPTION OF EXEMPLARY EMBODIMENTS

The following description of the embodiment(s) is merely exemplary (illustrative) in nature and is in no way intended to limit the invention, its application, or uses.

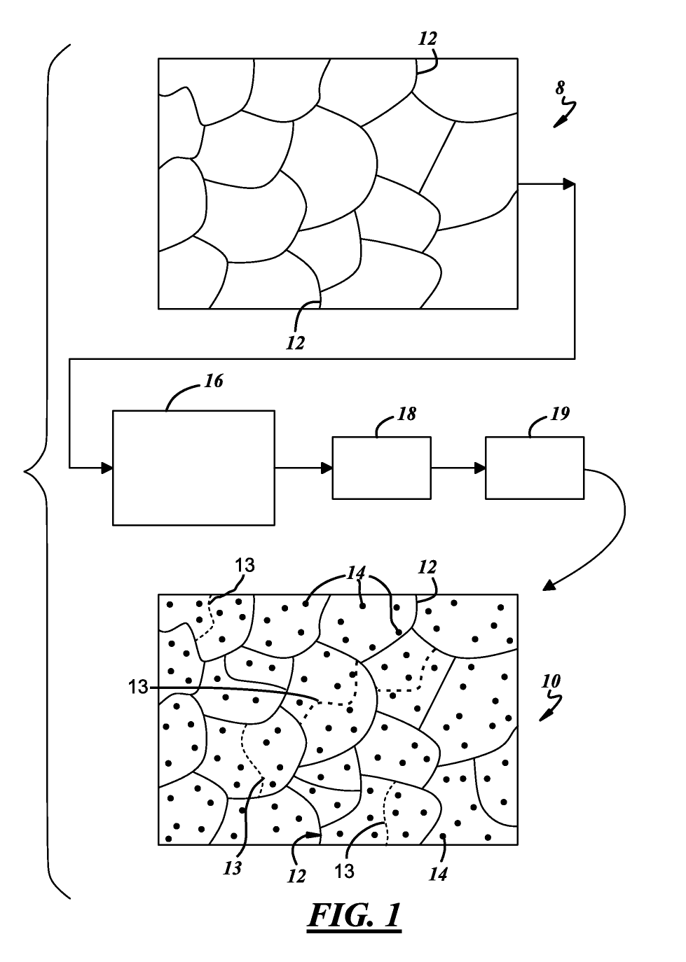

The exemplary embodiments, as shown in FIG. 1, describe a process of irradiating a thermoelectric material 8 using an irradiation device 16 to form an irradiated thermoelectric material 10 having improved thermoelectric properties. The thermoelectric material 8, prior to irradiation, may include grain boundaries 12. In one embodiment, the thermoelectric material 10 after irradiation may include new grain boundaries 13 in addition to grain boundaries 12. In another embodiment, the irradiated thermoelectric material 10 may also have other beneficial material defects including nanometer length scale (nano-scale) size defects 14, or features 14, that may be located at the existing grain boundaries 12, at the new grain boundaries 13, and/or in the interior of the grains constituting the irradiated thermoelectric material 10.

The enhancement of performance of the thermoelectric material 10 by irradiation as described above may manifest itself in a variety of engineering advantages when applied to specific devices, but in general may be expected to improve the materials thermoelectric figure of merit (ZT), which itself depends upon other material properties. These other material properties may include the Seebeck coefficient (S), electrical resistivity (ρ) and thermal conductivity (κ), such that ZT=S²T/κρ, where T is temperature.

Among the potential mechanisms by which radiation may enhance the material's ZT is a reduction in the material's thermal conductivity κ, which could be accomplished by the formation of nanometer length scale defects or features 14, such as those described in FIG. 1 above. The nature of these defects 14 may include point defects, crystallographic defects (such as the new grain boundaries 13 shown in FIG. 1, or lattice mismatching, or twinning, etc.) caused by elastic and inelastic scattering of the irradiation with atoms in the precursor thermoelectric material 8 (i.e. the material irradiated to form material 10).

Irradiation may lead to direct or immediate creation of the nano-scale defects 14 as described above, or the nano-scale defects 14 could emerge after heat treatment from a heat treatment device 18 and/or through a mechanical treatment device 19, which may be used in conjunction with the irradiation device 16 as shown in FIG. 1. The thermal or mechanical treatment may occur prior, during and/or after the radiation treatment. The nano-scale defects 14 may alternatively emerge as the result of other material processing of larger-scale irradiation-enhanced disorder as is known to those of ordinary skill in the art.

In one specific exemplary embodiment, the radiation used to modify the material 8 may be applied internally by incorporating specific isotopes of elements in the precursor alloy or thermoelectric material 8 that naturally undergoes radioactive decay and emits radiation spontaneously.

In another specific exemplary embodiment, the radiation used to modify the thermoelectric material 8 may be applied externally by irradiation of the thermoelectric material 8 that then undergoes nuclear reactions between the externally applied radiation and the nuclei, such as by neutron or other particle capture or by gamma ray absorption.

In either case (internally applied or externally applied), the excited nuclei subsequently undergo radioactive emissions or nuclear decay, thereby altering short range (crystal lattice) and/or long range (microstructure) material properties, thus yielding an optimized thermoelectric material 10 as illustrated above in FIG. 1.

Neutron irradiation may offer several conceptual advantages since it is expected to provide maximal penetration of the bulk material 8 (compared to charged particle or electromagnetic irradiation), causing both elastic and inelastic scattering defects 14, even to the point of amorphization. Some of these defects 14 may be self-healing above a critical temperature, so it is anticipated that for some materials, optimal irradiation conditions may require cryogenic temperatures to freeze in the defects 14 at the necessary densities and distributions, thus yielding metastable structures 10 at the operating temperatures for the applicable thermoelectric device.

The source for irradiation (i.e. the irradiation device 16) may be selected based on the requirements of radiation type (i.e. neutron, proton, ion, gamma ray, etc.), radiation energy, and radiation flux, which ultimately depend upon the elements used to make the thermoelectric material 8 and the type of radiation induced improvements to the thermoelectric material that are desired, wherein the improvements may include transmutation or otherwise displacing atoms out of their crystal lattice sites.

In one exemplary embodiment for neutron irradiation, the irradiation device 16 that may be utilized is a neutron beam. In another exemplary embodiment, the irradiation device 16 may be a particle accelerator.

In another exemplary method for irradiation, stable atomic nuclei may be utilized in the precursor thermoelectric material 8. Next, externally applied non-radioactively-inducing radiation may be applied to the material 8 after and during fabrication, keeping in mind that the starting chemical and isotope composition may need to be specifically altered, selected, or enriched to achieve the benefit. This irradiation may include ions and particles (neutrons, protons, electrons or photons) generated by typical accelerator or reactor technology. In this method, the radioactivity of the thermoelectric material 8 is never enhanced above natural background levels.

Furthermore, neutron radiation, both thermal and fast neutrons, can induce elemental transmutation, the radiological activation of a portion of the material's constituents. The transmuted elements may have a low solubility, or may even be insoluble, in their original crystalline matrix of the thermoelectric material 8, allowing them to diffuse relatively freely through the host lattice, or diffuse sufficiently under various heat treatment from heat treatment device 18 or mechanical processing from mechanical processing device 19 (for example, mechanical devices applying pressure or subjecting the material to stress), ultimately condensing as nano-scale intragranular inclusions (defects) 14 or grain-boundary structures 12. Additional defect transformations may occur as the transmuted species reverts to its original elemental species or it adopts a more stable isotopic form of yet another element. Even if the transmuted element remains in the original lattice as a stable isotope, like the nano-scale precipitates of transmuted elements, it represents a point defect 14 and a potential nano-scale inhomogeneity or defect that can lead to enhanced phonon scattering, and thus reduced thermal conductivity or improved thermoelectric power (Seebeck coefficient).

Other forms of radiation have their own advantages when it comes to potentially improving the performance of thermoelectric materials via phonon scattering from nano-scale defects 14. In the case of charged particle beams or ion bombardment from a device 16, defects 14 can be induced by direct ion implantation into the lattice or into inclusions, and/or the defects 14 can take the form of elongated scattering tracks created by the charged particles that could be tuned to a particular nanometer length scale based on the specific ion and kinetic energy used. In the case of photons, gamma rays, which are a high energy form of electromagnetic radiation, would be most likely to have a substantial impact on the modification and enhancement of thermoelectric materials. Although applying gamma radiation to thermoelectric materials is clearly innovative, for superconducting materials (e.g. Bi_{1.6}Pb_{0.4}Sr₂Ca₂Cu₃O₁₀) the critical current density has been observed to improve after gamma-irradiation (Superconductor Science & Technology 19 (1): 151-154 January 2006). For the enhancement of thermoelectric materials, coincident gamma rays and other forms of radiation may be particularly useful.

In still another exemplary embodiment, more than one irradiation technology as described above may also be applied, in series or in parallel, to the precursor thermoelectric material 8. This may also be done in combination with a sequence of thermal and/or mechanical treatments to further enhance the final product, depending upon its ultimate usage.

In one embodiment, the materials 8 that may have a relatively high cross section for inelastic scattering. Such exemplary materials 8 may transform during inelastic scattering, as opposed to simply creating isotopes of the same material. Further, such materials 8 may transmutate between atomic species. For example, the irradiation of a Zirconium atom may introduce an additional proton to the nucleus, therein generating a Niobium atom. Further, the irradiated material must not remain radioactive for too long after irradiation such that it is not desirable or available for use in a thermoelectric device. Other thermoelectric precursor materials may include the elements hafnium, vanadium, copper, antimony or tin.

One exemplary precursor alloy that may be benefit by irradiation by any of the above methods is ZrNiSn. ZrNiSn has a favorable cross-section for neutron capture. Another precursor alloy is YbAl₃. Still other precursor alloys are filled-skutterudites.

These irradiated materials 10 may find application in any number of uses and devices associated with thermal management. One non-limiting exemplary use is in waste heat recovery systems for automobiles. For example, these materials 10 may be a portion of a thermoelectric device associated with a vehicles exhaust system. Other waste heat recovery systems in which these materials may be used include but are not limited to power plants, fuel cells, or any industrial infrastructure having a large amount of heat. For example, such irradiated thermoelectric material having irradiation induced defect may be used to generate electricity from an energy source such as but not limited to waste heat generate by a vehicle, power plant, fuel cell, or industrial infrastructure.

The above description of embodiments of the invention is merely exemplary in nature and, thus, variations thereof are not to be regarded as a departure from the spirit and scope of the invention.

What is claimed is:

1. A method comprising:
providing the thermoelectric material;
irradiating the thermoelectric material to create nanometer length scale features in the thermoelectric material.

2. The method of claim 1, wherein said nanometer length scale features comprises one or more point defects.

3. The method of claim 1, wherein said nanometer length scale features comprises one or more crystallographic defects.

4. The method of claim 3, wherein said one or more crystallographic defects comprises one or more new grain boundaries formed in the thermoelectric material.

5. The method of claim 3, wherein said one or more crystallographic defects comprises lattice mismatching within the thermoelectric material.

6. The method of claim 3, wherein said one or more crystallographic defects comprises twinning within said the thermoelectric material.

7. The method of claim 1, wherein said nanometer length scale defects within the thermoelectric material comprises one or more of point defects and crystallographic defects.

8. The method of claim 1, wherein irradiating said thermoelectric material induces elemental transmutation in said thermoelectric material.

9. The method of claim 1, wherein irradiating said thermoelectric material induces new elements into said thermoelectric material by ion implantation.

10. The method of claim 1, wherein irradiating said thermoelectric material incorporates specific isotopes of elements in said thermoelectric material.

11. The method of claim 1, wherein irradiating said thermoelectric material comprises neutron irradiation.

12. The method of claim 1, further comprising heat treating said thermoelectric material.

13. The method of claim 1, further comprising using the irradiated thermal electric device to generate electricity from an energy source.

14. A method for enhancing the thermoelectric figure of merit of a thermoelectric material comprising:
providing the thermoelectric material;
providing a first irradiation device;
introducing the thermoelectric material within said first irradiation device; and
irradiating the thermoelectric material to create nanometer length scale features in the thermoelectric material.

15. The method of claim 14 further comprising:
providing a second irradiation device;
irradiating the thermoelectric material within said second irradiation device, wherein the irradiation of the thermoelectric material in said first irradiation device and said second irradiation device creates nanometer length scale features in the thermoelectric material.

16. The method of claim 15, wherein the irradiation of the thermoelectric material within said first irradiation device and within said second irradiation device are done in series.

17. The method of claim 15, wherein the irradiation of the thermoelectric material within said first irradiation device and within said second irradiation device are done in parallel.

18. The method of claim 14 further comprising heat treating the thermoelectric material with a heat treatment device.

19. The method of claim 14, wherein said first radiation device comprises a neutron beam device.

20. The method of claim 14, wherein said first radiation device comprises a particle accelerator.
